(19) United States
(12) Patent Application Publication
(10) Pub. No.: US 2011/0076794 A1
(43) Pub. Date: Mar. 31, 2011

(54) METHOD OF MAKING A VERTICALLY STRUCTURED LIGHT EMITTING DIODE

(76) Inventors: Ming-Cheng Lo, Tainan County (TW); Hung-Jen Chen, Tainan County (TW); Juh-Yuh Su, Tainan County (TW)

(21) Appl. No.: 12/872,560

(22) Filed: Aug. 31, 2010

(30) Foreign Application Priority Data
Sep. 29, 2009 (TW) 098132917

(51) Int. Cl. H01L 33/02

(52) U.S. Cl. 438/47; 257/E33.023

(57) ABSTRACT

A method of making a vertically structured light emitting diode includes: providing a sacrificial substrate having first and second portions; forming a first buffer layer on a surface of the sacrificial substrate; forming a second buffer layer on a surface of the first buffer layer; forming a light emitting unit on a surface of the second buffer layer; forming a device substrate on a surface of the light emitting unit; etching the first portion of the sacrificial substrate such that the second portion of the sacrificial substrate remains on the first buffer layer; dry-etching the second portion of the sacrificial substrate; dry-etching the first buffer layer; and etching the second buffer layer. An etch rate of a material of the second buffer layer is lower than an etch rate of a material of the first buffer layer.

### CROSS-REFERENCE TO RELATED APPLICATION

This application claims priority of Taiwanese application no. 098132917, filed on Sep. 29, 2009.

### BACKGROUND OF THE INVENTION

1. Field of the Invention

This invention relates to a method of making a light emitting diode, more particularly to a method of making a vertically structured light emitting diode.

2. Description of the Related Art

A conventional method of making a vertically structured light emitting diode (LED) includes growing a gallium nitride (GaN) based epitaxial structure on a sapphire (Al₂O₃) substrate, removing the sapphire substrate using a laser lift-off process, and attaching the GaN-based epitaxial structure to another substrate which has better thermal conductivity than that of the sapphire substrate.

When the laser lift-off process is conducted, all portions of the sapphire substrate are irradiated by laser beams such that decomposition of a GaN interfacial layer between the GaN-based epitaxial structure and the sapphire substrate occurs. Accordingly, the sapphire substrate can be removed. However, during the laser lift-off process, the GaN-based epitaxial structure is also irradiated by the laser beams, thereby inducing a chemical reaction. Accordingly, an active layer of the GaN-based epitaxial structure may be easily damaged. Since recombination of electron-hole pairs occurs in the active layer so as to release energy in the form of light, damage to the active layer leads to a reduction in the light emitting efficiency. Thus, the laser lift-off process is not a satisfactory way to remove the sapphire substrate.

Removal of a sapphire substrate by laser irradiation is disclosed in U.S. Pat. No. 7,442,644. This patent discloses a method of manufacturing a nitride semiconductor device in which buffer layers are formed between a sapphire substrate and a nitride semiconductor. The sapphire substrate is removed by laser irradiation, and the buffer layers are removed by etching.

### SUMMARY OF THE INVENTION

Therefore, the object of the present invention is to provide a method of making a vertically structured light emitting diode, which dispenses with laser irradiation for removal of a sapphire substrate.

According to this invention, a method of making a vertically structured light emitting diode comprises: providing a sacrificial substrate having a first portion and a second portion; forming a first buffer layer on a surface of the sacrificial substrate so that the second portion of the sacrificial substrate is disposed between the first portion of the sacrificial substrate and the first buffer layer; forming a second buffer layer on a surface of the first buffer layer opposite to the sacrificial substrate; forming a light emitting unit on a surface of the second buffer layer opposite to the first buffer layer; forming a device substrate on a surface of the light emitting unit opposite to the second buffer layer; etching the first portion of the sacrificial substrate such that the second portion of the sacrificial substrate remains on the first buffer layer; dry-etching the second portion of the sacrificial substrate; dry-etching the first buffer layer; and etching the second buffer layer. An etch rate of a material of the second buffer layer is lower than an etch rate of a material of the first buffer layer.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a flowchart to show the preferred embodiment of a method of making a vertically structured light emitting diode according to the present invention; and

FIG. 2 illustrates several steps of the preferred embodiment shown in FIG. 1.

### DETAILED DESCRIPTION OF THE PREFERRED EMBODIMENT

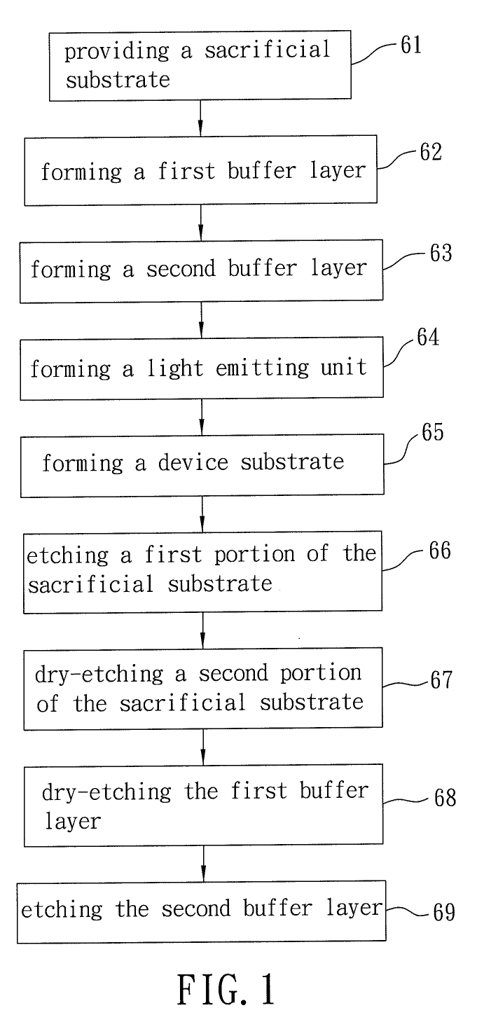

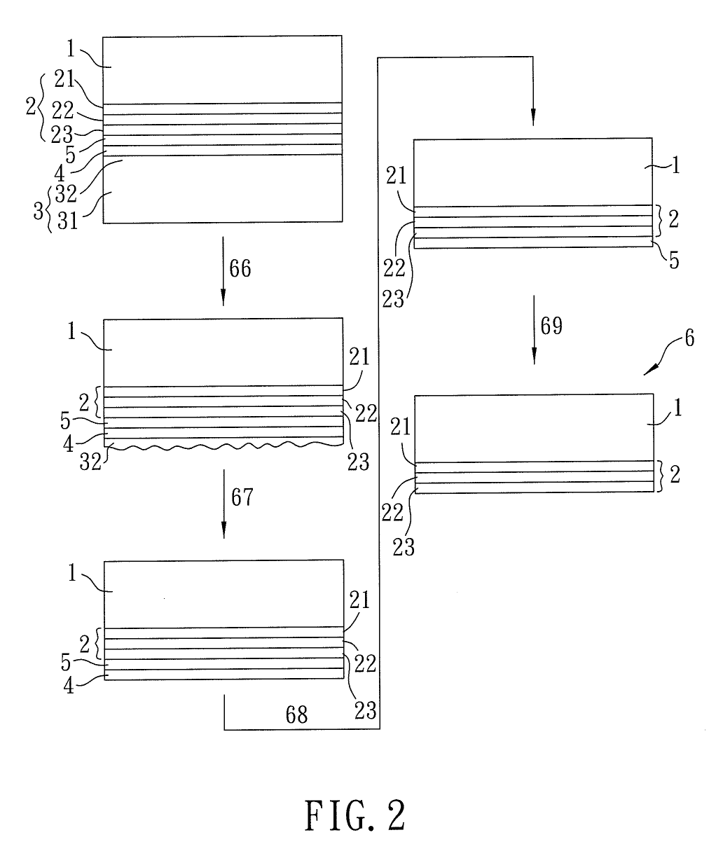

Referring to FIGS. 1 and 2, according to the present invention, the preferred embodiment of a method of making a vertically structured light emitting diode (LED) is described as follows. A vertically structured LED 6 made using the preferred embodiment of the method of the present invention is a gallium nitride (GaN) based LED.

In step 61, a sacrificial substrate 3 is provided. The sacrificial substrate 3 has a first portion 31 and a second portion 32 on the first portion 31. The sacrificial substrate 3 in this embodiment is a sapphire (Al₂O₃) substrate. In step 62, a first buffer layer 4 is formed on a surface of the sacrificial substrate 3 so that the second portion 32 of the sacrificial substrate 3 is disposed between the first portion 31 of the sacrificial substrate 3 and the first buffer layer 4. The first buffer layer 4 in this embodiment includes undoped GaN. In step 63, a second buffer layer 5 is formed on a surface of the first buffer layer 4 opposite to the sacrificial substrate 3. The second buffer layer 5 may include AlₓGa₍₁₋ₓ₎N or InₓGa₍₁₋ₓ₎N, and has a thickness approximately ranging from tens of nanometers to hundreds of nanometers.

In step 64, a light emitting unit 2 is formed on a surface of the second buffer layer 5 opposite to the first buffer layer 4. The light emitting unit 2 includes a first cladding layer 21 that is a p-type semiconductor made from a GaN-based material, a second cladding layer 23 that is an n-type semiconductor made from a GaN-based material, and an active layer 22 that may have a GaN-based homojunction structure, a GaN-based heterojunction structure, or a multiple quantum well (MQW) structure. In a direction away from the second buffer layer 5, the n-type second cladding layer 23, the active layer 22, and the p-type first cladding layer 21 are sequentially formed. It should be noted that the light emitting unit 2 may include other elements in other embodiments.

In step 65, a device substrate 1 is formed on a surface of the first cladding layer 21 of the light emitting unit 2. The device substrate 1 is a substrate that has good electrical and thermal conductivity (e.g., a metallic substrate). In this embodiment, the device substrate 1 is a copper substrate. The device substrate 1 may be bonded to the light emitting unit 2 by virtue of a wafer bonding technique.

In step 66, the first portion 31 of the sacrificial substrate 3 is etched such that the second portion 32 of the sacrificial substrate 3 remains on the first buffer layer 4. In this embodiment, the first portion 31 of the sacrificial substrate 3 is etched through a chemical-mechanical polishing (CMP) process until the sacrificial substrate 3 has a thickness of about 10 μm (i.e., the second portion 32 of the sacrificial substrate 3 has the thickness of about 10 μm). Therefore, most of the sacrificial substrate 3 (i.e., the first portion 31) is removed. The second portion 32 of the sacrificial substrate 3 has an uneven surface (see FIG. 2).

In step 67, the second portion 32 of the sacrificial substrate 3 is dry-etched. Generally, a dry-etching process may be physical etching, chemical etching, or a combination of physical and chemical etching. In this embodiment, the second portion 32 of the sacrificial substrate 3 is dry-etched through an inductively coupled plasma (ICP) etching process, and the ICP etching process employs a suitable reactant gas and argon to remove the second portion 32 of the sacrificial substrate 3. Specifically, argon leads to physical etching by bombarding the second portion 32 of the sacrificial substrate 3, and the reactant gas results in chemical etching. The reactant gas may be selected from the group consisting of chlorine, boron trichloride, carbon tetrafluoride, trifluoromethane, sulfur hexafluoride, oxygen, and combinations thereof. An end-point detection system (not shown) is used to detect an etch rate. Since the materials of the second portion 32 of the sacrificial substrate 3 and the first buffer layer 4 are different, an etch rate of the second portion 32 of the sacrificial substrate 3 and an etch rate of the first buffer layer 4 are different. Therefore, an etch rate change occurs at an interface between the second portion 32 of the sacrificial substrate 3 and the first buffer layer 4 such that the ICP etching process can be automatically terminated at the interface between the second portion 32 of the sacrificial substrate 3 and the first buffer layer 4. Namely, the ICP etching process can be set to only act on a desired element (e.g., the second portion 32 of the sacrificial substrate 3). By virtue of the suitable reactant gas, a proper pressure, and the end-point detection system, the second portion 32 of the sacrificial substrate 3 can be completely removed without damaging the first buffer layer 4.

In step 68, the first buffer layer 4 is dry-etched. In this embodiment, the first buffer layer 4 is dry-etched using the ICP etching process. Similarly, the ICP etching process employs the suitable reactant gas and argon so as to remove the first buffer layer 4. The ICP etching process can also be set to only act on the first buffer layer 4 so that etching can be automatically terminated at an interface between the first and second buffer layers 4,5. The first buffer layer 4 can be hence completely removed without damaging the second buffer layer 5.

In step 69, the second buffer layer 5 is etched. Consequently, the vertically structured LED 6 is formed. In this embodiment, the ICP etching process is also performed to etch the second buffer layer 5, and can be set to only act on the second buffer layer 5. Accordingly, etching can be automatically terminated at an interface between the second buffer layer 5 and the light emitting unit 2. The second buffer layer 5 can be completely removed without damaging the light emitting unit 2.

After removal of the second buffer layer 5, an element, such as an ohmic contact layer (not shown), an electrode (not shown), etc., can be disposed on a surface of the light emitting unit 2. Since the feature of the invention does not reside in a process of disposing the aforementioned element(s) on the surface of the light emitting unit 2, which is known in the art, further details of the same are omitted herein for the sake of brevity.

Since the CMP process and the ICP etching process are able to replace the laser lift-off process, the light emitting unit 2 is not irradiated by laser beams and is hence prevented from being damaged by the same. Via the CMP process, an etch depth can be controlled. Through the dry-etching process like the ICP etching process, an etch rate can be easily controlled, and etching can be automatically terminated. Therefore, the desired element (e.g., the second portion 32 of the sacrificial substrate 3, the first buffer layer 4, and the second buffer layer 5) can be completely removed without damaging an undesired element. Furthermore, compared to a wet-etching process, an etch rate of the dry-etching process can be more effectively controlled.

The second buffer layer 5 serves as an end-point of the second dry-etching process (i.e., the second ICP etching process) such that the light emitting unit 2 can be prevented from being immediately etched after the removal of the first buffer layer 4. Preferably, an etch rate of a material of the second buffer layer 5 is lower than that of the material of the first buffer layer 4. Consequently, the etching of the second buffer layer 5 can be more easily controlled compared to the etching of the first buffer layer 4. Accordingly, the light emitting unit 2 can be prevented from being damaged.

In this embodiment, the etch rates of the materials of the first and second buffer layers 4,5 have the following relation:

y≧1.5x

where the etch rate of the material of the first buffer layer 4 is y, and the etch rate of the material of the second buffer layer 5 is x. In this embodiment, the etch rate of the material of the second portion 32 of the sacrificial substrate 3 and the etch rate of the material of the first buffer layer 4 have the following relation:

z≧1.5y

where the etch rate of the material of the second portion 32 of the sacrificial substrate 3 is z, and the etch rate of the material of the first buffer layer 4 is y. By virtue of the difference between z and y, the ICP etching process can be set to only act on the second portion 32 of the sacrificial substrate 3 in step 67.

Due to the method of this invention, the surface of the light emitting unit 2 is even, and a structure of the light emitting unit 2 is not damaged. Therefore, the vertically structured LED 6 made using the method of this invention has a satisfactory epitaxial structure and high light emitting efficiency.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. A method of making a vertically structured light emitting diode, comprising:
providing a sacrificial substrate having a first portion and a second portion;
forming a first buffer layer on a surface of the sacrificial substrate so that the second portion of the sacrificial substrate is disposed between the first portion of the sacrificial substrate and the first buffer layer;
forming a second buffer layer on a surface of the first buffer layer opposite to the sacrificial substrate;
forming a light emitting unit on a surface of the second buffer layer opposite to the first buffer layer;
forming a device substrate on a surface of the light emitting unit opposite to the second buffer layer;
etching the first portion of the sacrificial substrate such that the second portion of the sacrificial substrate remains on the first buffer layer;
dry-etching the second portion of the sacrificial substrate;
dry-etching the first buffer layer; and
etching the second buffer layer,
wherein an etch rate of a material of the second buffer layer is lower than an etch rate of a material of the first buffer layer.

2. The method of claim 1, wherein the first portion of the sacrificial substrate is etched through a chemical-mechanical polishing process.

3. The method of claim 1, wherein the second portion of the sacrificial substrate is dry-etched through an inductively coupled plasma etching process.

4. The method of claim 3, wherein the inductively coupled plasma etching process employs a reactant gas selected from the group consisting of chlorine, boron trichloride, carbon tetrafluoride, trifluoromethane, sulfur hexafluoride, and oxygen.

5. The method of claim 1, wherein the first buffer layer is dry-etched through an inductively coupled plasma etching process.

6. The method of claim 5, wherein the inductively coupled plasma etching process employs a reactant gas selected from the group consisting of chlorine, boron trichloride, carbon tetrafluoride, trifluoromethane, sulfur hexafluoride, and oxygen.

7. The method of claim 1, wherein the second buffer layer is etched through an inductively coupled plasma etching process.

8. The method of claim 7, wherein the inductively coupled plasma etching process employs a reactant gas selected from the group consisting of chlorine, boron trichloride, carbon tetrafluoride, trifluoromethane, sulfur hexafluoride, and oxygen.

9. The method of claim 1, wherein the etch rates of the materials of the first and second buffer layers have the following relation:
y≧1.5x
where the etch rate of the material of the first buffer layer is y, and the etch rate of the material of the second buffer layer is x.

10. The method of claim 1, wherein an etch rate of a material of the second portion of the sacrificial substrate and the etch rate of the material of the first buffer layer have the following relation:
z≧1.5y
where the etch rate of the material of the second portion of the sacrificial substrate is z, and the etch rate of the material of the first buffer layer is y.

11. The method of claim 1, wherein the sacrificial substrate is a sapphire substrate.

12. The method of claim 1, wherein the first buffer layer includes undoped GaN.

13. The method of claim 1, wherein the second buffer layer includes AlₓGa₍₁₋ₓ₎N.

14. The method of claim 1, wherein the second buffer layer includes InₓGa₍₁₋ₓ₎N.

15. The method of claim 2, wherein each of the second portion of the sacrificial substrate, the first buffer layer, and the second buffer layer is dry-etched through an inductively coupled plasma etching process.

16. The method of claim 15, wherein the sacrificial substrate is a sapphire substrate, the first buffer layer includes undoped GaN, and the second buffer layer includes one of AlₓGa₍₁₋ₓ₎N and InₓGa₍₁₋ₓ₎N.
